(19) United States
(12) Patent Application Publication
(10) Pub. No.: US 2023/0345651 A1
(43) Pub. Date: Oct. 26, 2023

(54) ASSEMBLY CONFIGURED TO SUPPORT A DISPLAY SCREEN WHICH IS ADJUSTABLE ACCORDING TO VIEWING MODES, DISPLAY MODULE, AND MULTIMEDIA DEVICE

(71) Applicants: Fuyun Acoustics Technology (shenzhen) Co., Ltd., Shenzhen (CN); Foxconn Technology Group Co., Ltd., Shenzhen (CN); HON HAI PRECISION INDUSTRY CO., LTD., New Taipei (TW)

(72) Inventors: MEI-TAO ZHANG, Shenzhen (CN); HSIU-YING LI, New Taipei (TW)

(21) Appl. No.: 17/872,161

(22) Filed: Jul. 25, 2022

(30) Foreign Application Priority Data
Apr. 22, 2022 (CN) 202210431705.3

(51) Int. Cl. H05K 5/02; H05K 5/00

(52) U.S. Cl. CPC H05K 5/0217; H05K 5/0018

(57) ABSTRACT

An assembly configured to support a display screen which is adjustable according to viewing modes, either in a horizontal or a vertical orientation to suit images being viewed. The assembly includes two side support brackets, a top support bracket, a bottom support bracket, and a protection frame. The two side support brackets positioned on both sides of a display screen along a first direction to limit the movement of the display screen. Top and bottom support brackets arranged at both ends along a second direction clamp the display screen. The protection frame on two sides of the top support bracket and the bottom support bracket protect the sides of the display screen. The first direction is perpendicular to the second direction. A display module mounted on boxbody is also disclosed. A multimedia device is also disclosed.

### FIELD

The subject matter herein relates to displays, especially relates to assembly configured to support a display screen which is adjustable according to viewing modes, display module and multimedia device.

### BACKGROUND

A display screen is generally fixed in the multimedia device in a horizontal location. The display screen cannot easily be switched relative to the multimedia device from the horizontal location to a vertical location to adopt to a change in display mode of the display screen.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric, assembled view of a multimedia device in an embodiment of the present disclosure.

FIG. 2 is an isometric, exploded view of the multimedia device shown in FIG. 1.

FIG. 3 is similar to FIG. 1, but viewed from another aspect.

FIG. 4 is an isometric view of a support assembly in the multimedia device of FIG. 1.

FIG. 5 is an isometric view of a support assembly according to another embodiment.

FIG. 6 is an isometric, exploded view of the support assembly.

### DETAILED DESCRIPTION

In order to make the above-mentioned objects, features, and advantages of the present application more obvious, a description of specific embodiments of the present application will be described with reference to the accompanying drawings. The present application can be implemented in many ways different from those described herein, and those skilled in the art can make similar improvements without violating the contents of the present application. Therefore, the present application is not to be considered as limiting the scope of the embodiments to those described herein.

Several definitions that apply throughout this disclosure will now be presented.

Unless otherwise defined, all technical and scientific terms used herein have the same meaning as commonly understood by one skilled in the art. The terms used in the present application herein are only for describing specific embodiments, and are not intended to limit the present application.

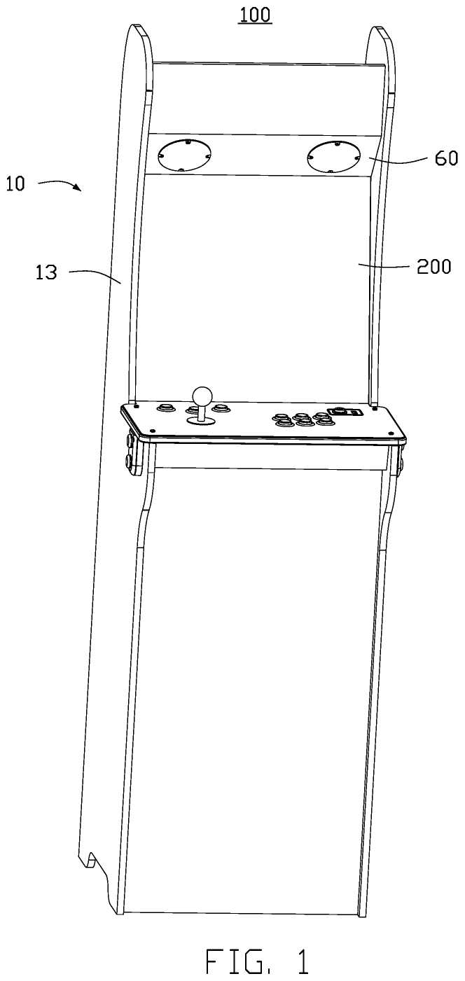

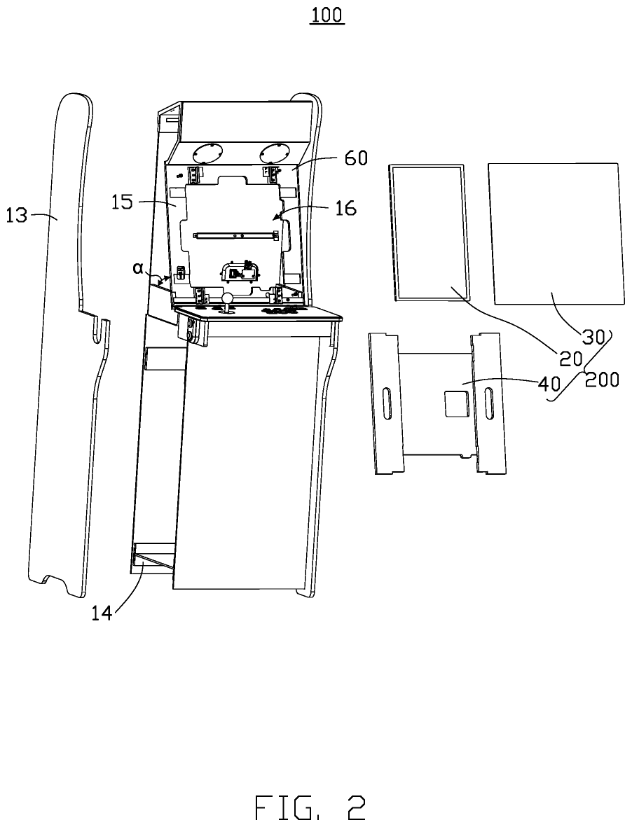

Referring to FIGS. 1 and 2, an embodiment of the present application provides a multimedia device 100. The multimedia device 100 can switch between a horizontal display mode and a vertical screen display mode according to the functions and scenes used. The multimedia device 100 can adapt to the user's usage habits, and improves the user experience.

The multimedia device 100 includes a box body 10, a display module 200, and four first connectors 60. The box body 10 includes a display window 16, and the display window 16 is positioned to correspond to the display module 200. The display module 200 is detachably installed on the box body 10 by the four first connectors 60, a position of the display module 200 correspond to the display window 16. The four first connectors 60 are arranged in a square, and a center axis of the square coincides with a central axis of the display module 200. A coincidence mentioned here is allowed to have a deviation of 10% relative to the length of the sides of the square formed by the four first connectors 60.

When the horizontal display mode and vertical display mode need to be switched, the display module 200 needs to be removed and then reinstalled in the alternative mode. Further, the conversion method is to rotate the display module 200 by 90°, because the four first connectors 60 are arranged in a square, and the central axis of the square coincides with the central axis of the display module 200. When the display module 200 is rotated by 90°, the positions of the four first connectors 60 on the display module 200 and the box body 10 remain effectively unchanged.

Referring to FIGS. 1 and 2, in an embodiment, the box body 10 includes a first housing 11 and a second housing 12. The first housing 11 and the second housing 12 are detachably connected to facilitate the maintenance or processing of the first housing 11 and the second housing 12 respectively.

The box body 10 also includes two side plates 13 and a connecting plate 14. The ends of the connecting plate 14 are connected to the two side plates 13 by fasteners. Preferably, the fastener includes a screw and a nut. The screw is positioned on the side plate 13. One end of the screw is positioned on the connecting plate 14, and the other end is connected with the nut on the side plate 13. The fasteners make it unnecessary to define threaded holes on the side plate 13, so that the outer surface of the side plate 13 is complete for an aesthetic advantage.

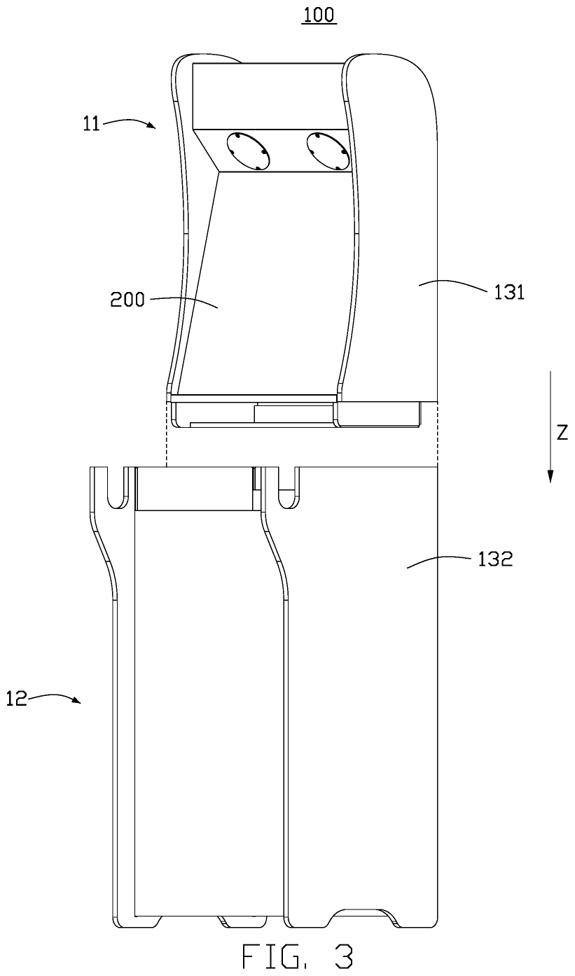

Referring to FIG. 3, in an embodiment, the side plate 13 includes a first side plate 131 and a second side plate 132. The first side plate 131 and the second side plate 132 are arranged along the third direction Z. The first side plate 131 and the second side plate 132 are detachably connected.

In an embodiment, the first side plate 131 and the second side plate 132 can be mounted with bolts. For example, the first side plate 131 and the second side plate 132 each define a threaded hole, and the bolts are used to extends through the threaded hole of the first side plate 131 and the second side plate 132. The first side plate 131 and the second side plate 132 are connected so that the first housing 11 and the second housing 12 are mounted. The first side plate 131 and the second side plate 132 may also be connected by snap connection or interference fit, which is not limited herein.

In another embodiment, the first side plate 131 and the second side plate 132 are integrally formed, which can reduce the number of openings in molding and reduce the cost.

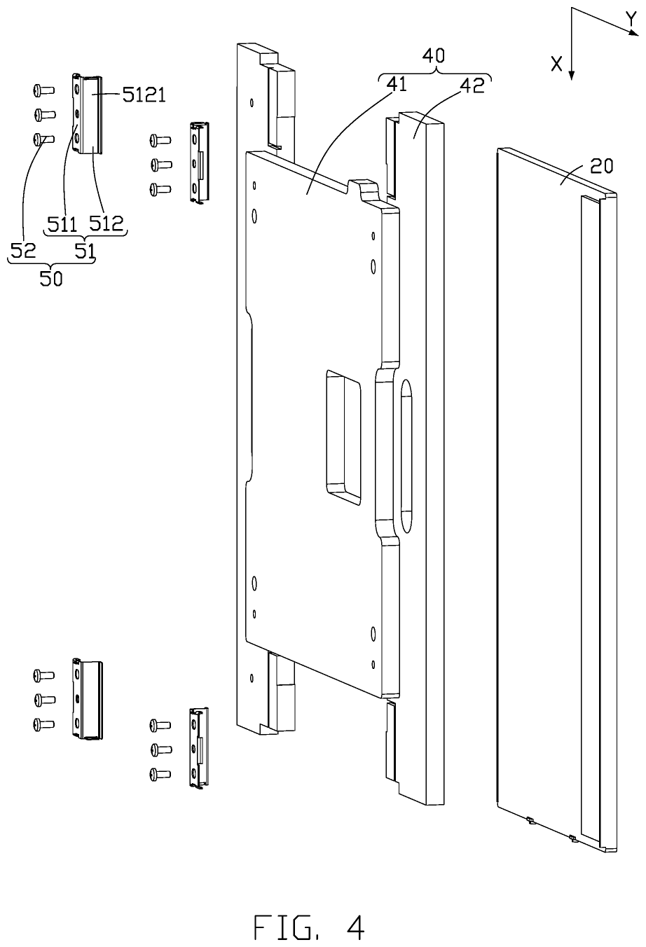

Referring to FIG. 4, in an embodiment, the display module 200 includes a display screen 20 and an assembly 40 to support the display screen 20 which is adjustable according to viewing modes. The display screen 20 and the assembly 40 are detachably connected. The assembly 40 is connected to the box body 10 by the first connector 60. The display screen 20 is connected to the box body 10 by the assembly 40. Compared with a direct connection between the display screen 20 and the box body 10, the display screen 20 being connected to the box body 10 by the assembly 40 reduces the difficulty of connection and reduces possible damage to the display screen 20 during connection.

Referring to FIGS. 3 and 4, for convenience of description, the length direction of the display screen 20 is defined as the first direction X, the width direction is the second direction Y, and the first direction X is perpendicular to the second direction Y. The extending wise direction of the box body 10 is the third direction Z.

The display screen 20 may include RGB (red, green, blue) light-emitting diodes (Light Emitting Diode), LCD (Liquid Crystal Display), LCOS (Liquid Crystal on Silicon) devices, OLED (Organic Light-Emitting Diode) array, projection, laser, laser diode, or any other suitable imaging modality, which is not limited herein.

In some embodiments, the display screen 20 adopts a high-brightness display device, high-brightness referring to a display device with a brightness of more than 500 cd/m 2, which can improve the display quality. In practical application, the display brightness of the display screen 20 can also be adjusted according to the brightness of ambient light.

Referring to FIGS. 2 and 4, in an embodiment, a length of the assembly 40 along the first direction X and a length along the second direction Y are equal. The outer circumference of the assembly 40 is a square. The display screen 20 is detachably mounted on the assembly 40, and the assembly 40 is detachably mounted on the box body 10. The display screen 20 is detachably mounted on the display window 16 by the assembly 40.

By setting the outer circumference of the assembly 40 to be a square, the displaying window 16 can also be made as a square. For the time being, the assembly 40 can be aligned with the edge of the displaying window 16 in both horizontal display mode and vertical display mode. The assembly 40 is aligned with the edge of the display windows 16, so that there is no gap between the display window 16 and the assembly 40, and the appearance of the entire multimedia device 100 is improved.

Referring to FIG. 2, in an embodiment, display module 200 also includes a glass panel 30. The glass panel 30 is positioned on the displaying window 16 to protect a display surface of the display screen 20 from external factors.

Referring to FIG. 2 again, in an embodiment, the box body 10 also includes fixing plate 15. The fixing plate 15 is detachably connected to the display module 200. The assembly 40 is connected to the first connector 60 by the fixing plate 15. Further, when the first connector 60 is the first bolt, the assembly 40 is connected to the fixing plate 15 by the first bolt. The fixing plate 15, the assembly 40, and the glass panel 30 are defined as through holes. The first bolts pass through the through holes in the glass panel 30, the assembly 40 and the fixing plate 15 in sequence to mount the display screen 20 and the box body 10. When the display screen 20 needs to be switched between horizontal and vertical screens, loosening or unscrewing the first bolt is the only action required, then rotate the assembly 40 by 90° and tighten the first bolt to remount it.

In an embodiment, a dihedral angle formed between the plane where the fixing plate 15 is located and the plane perpendicular to the third direction Z is α, where 45°≤α≤90°. When the display screen 20 is placed on the fixing plate 15, a dihedral angle formed between the plane where the display screen 20 is located and the plane perpendicular to the third direction Z is also α. The display screen 20 is positioned in this way that is beneficial for the user to have a display frame suitable in mode for what is being viewed.

Further , 60°≤α≤80°, the display screen 20 is positioned in a way that is convenient for the user to see a large display frame. For example, if the user only needs to see part of the display screen 20, the size and position of the actual display frame is freely adjustable, not being limited herein.

Referring to FIG. 4, in an embodiment, the assembly 40 includes a support panel 41 and two side support plates 42. The two side support plates 42 are positioned on both sides of the support panel 41 along the first direction X. The two side support plates 42 are connected to the support panel 41. The display module 200 also includes a second connector 50. The display screen 20 is connected to the two side support plates 42 by the second connector 50. The two side support plates 42 allow the mounting of the display screen 20 and can also protect the two sides of the display screen 20.

The two side support plates 42 and the support panel 41 are detachably connected to facilitate the maintenance of the two side support plates 42 and the support panel 41. For example, after removing the second connector 50 from the support panel 41, the support panel 41 and the two side support plates 42 can be split apart.

In another embodiment, the two side support plates 42 and the support panel 41 can also be integrally formed, which reduces the number of molded openings and costs.

In an embodiment, the support panel 41 is made of a wooden board. The wooden board is sturdy and durable, and easy to process and shape. Also, a wooden board is non-conductive, preventing the internal components of the multimedia device 100 from being short-circuited by the support panel 41.

In an embodiment, a display surface of the side support plate 42 and a display surface of the display screen 20 are in the same plane. By setting the two display surfaces on the same plane, the two side support plates 42 can protect the two side of the display screen 20 without blocking the display frame of the display screen 20.

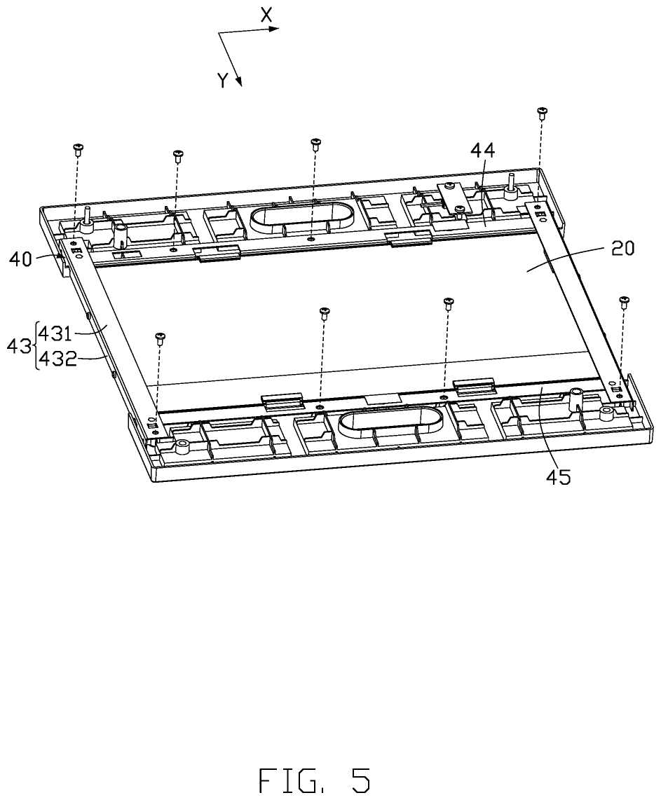

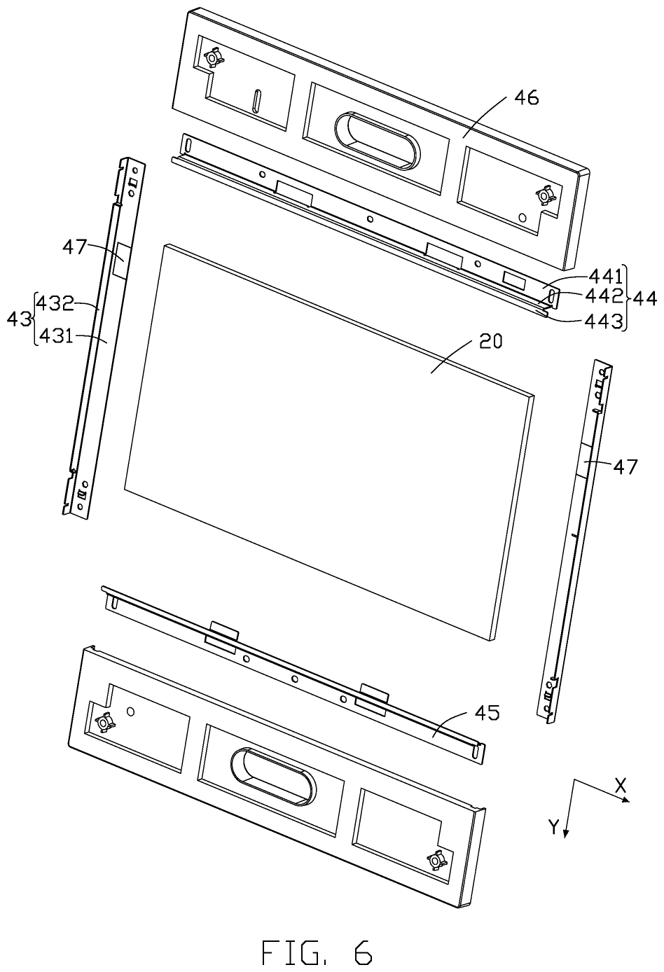

Referring to FIGS. 5 and 6, in an embodiment, the assembly 40 includes two side support brackets 43. The two side support brackets 43 are positioned on the sides of the display screen 20, respectively, along the first direction X to limit a movement of the display screen 20.

The side support brackets 43 include a first support plate 431 and a first baffle 432. The first support plate 431 and the first baffle 432 are arranged in an L shape. The first support plate 431 and the first baffle 432 are detachably connected. For example, the first support plate 431 and the first baffle 432 are connected by a bolt. Or, the first support plate 431 defines a hole and the first baffle 432 includes a bump, the bump being mounted in the hole. In another embodiment, the first support plate 431 and the first baffle 432 can also be integrally formed.

The first support plate 431 contacts a side of the display screen 20 away from the display surface. The first support plate 431 is used to support the display screen 20. The first baffle 432 contacts a side of the display screen 20 perpendicular to the first direction X. Two first baffles 432 cooperate to clamp the display screen 20 along the first direction X for limiting the movement of the display screen 20 along the first direction X and also protect the two sides of the display screen 20.

In an embodiment, assembly 40 also includes a buffer member 47. The buffer member 47 is mounted on the first support plate 431. The buffer member 433 can be foam or rubber pad. When the display screen 20 is positioned on the side support bracket 43, impacts or blows on the display screen 20 have a reduced effect by setting the buffer member.

Referring to FIGS. 5 and 6, in other embodiment, the assembly 40 also includes a top support bracket 44 and a bottom support bracket 45. The top support bracket 44 and the bottom support bracket 45 are arranged at both ends of the display screen 20 along the second direction Y. The top support bracket 44 and the bottom support bracket 45 cooperate to clamp the display screen 20 for limiting the movement of the display screen 20, respectively, along the second direction Y.

In an embodiment, the top support bracket 44 and the bottom support bracket 45 have a same structure, which improve manufacturing ease.

The top support bracket 44 includes a second support plate 441 and a second baffle 442. The second support plate 441 and the second baffle 442 are arranged in an L shape. The second support plate 441 and the second baffle 442 are detachably connected. For example, the second support plate 441 and the second baffle 442 are connected by a bolt. Or, the second support plate 441 defines another hole and the second baffle 442 includes another bump, the other bump being mounted in the other hole.

Both ends of the second support plate 441 are connected with the two side support brackets 43. The second baffle 442 is perpendicular to the second direction Y. Two second baffles 442 cooperate to clamp the display screen 20 for limiting the movement of the display screen 20 along the second direction Y and can also protect the two side of the display screen 20. In an embodiment, the buffer member 47 is mounted at the position where the second baffle 442 is in physical contact with the display screen 20.

Referring to FIG. 6, in an embodiment, the top support bracket 44 also includes a first extending component 443. The first extending component 443 is positioned at one end of the second baffle 442 away from the second support plate 441, and is formed by extending a distance along the second direction Y. The first extending component 443 is used to protect the corners of the display screen 20.

In an embodiment, both ends of the top support bracket 44 and both ends of the bottom support bracket 45 are provided with lock nuts. The top support bracket 44 and the bottom support bracket 45 are mounted in the side support bracket 43 by a third bolt with lock nuts to improve the stability of the assembly 40.

Referring to FIG. 6, in an embodiment, the assembly 40 also includes a protection frame 46. The protection frame 46 is positioned on the side of the top support bracket 44 and the bottom support bracket 45 along the second direction Y. The protection frame 46 is used to protect the side of the display screen 20. The side of the top support bracket 44 is away from the side of the bottom support bracket 45.

In an embodiment, the top support bracket 44 and the bottom support bracket 45 are connected the protection frame 46 by a connector. Further, the top support bracket 44, the bottom support bracket 45, and the protection frame 46 each define a threaded hole. The connector is a bolt. The bolt passes through the threaded hole of the top support bracket 44 and the protection frame 46 to realize the connection between the top support bracket 44 and the protection frame 46, and then passes through the threaded hole of the bottom support bracket 45 and the protection frame 46 to realize the connection between the bottom support bracket 45 and the protection frame 46.

In an embodiment, a display surface of the protection frame 46 and a display surface of the display screen 20 are in the same plane. By setting the two display surfaces on the same plane, the protection frame 46 can protect the two sides of the display screen 20 without blocking the display frame of the display screen 20.

In an embodiment, the protection frame 46 is made of plastic material. Plastic material is cheap and easy to process and shape. The protection frame 46 is black, providing a better contrast with images appearing on the display screen 20.

Referring to FIG. 4, in an embodiment, the second connector 50 includes a connecting piece 51 and a second bolt 52. The connecting piece 51 includes a first surface 511 and a second surface 512. The first surface 511 and the second surface 512 are arranged in an L shape. The first surface 511 and the assembly 40 each define a threaded hole, the second bolt 52 passes through the threaded hole to connect the second connector 50 and the assembly 40. The second surface 512 is perpendicular to the second direction Y.

The display module 200 includes two second connectors 50 along the second direction Y. The two second surfaces 512 cooperate to clamp the display screen 20 along the second direction Y.

Referring to FIG. 4, in an embodiment, the second surface 512 includes a second extending component 5121. The second extending component 5121 is positioned at one end of the second surface 512 away from the first surface 511, and is formed by extending a distance along the second direction Y. The second extending component 5121 is used to protect the corners of the display screen 20.

In an embodiment, the display module 200 includes four second connectors 50. The four second connectors 50 are arranged at four corners of the assembly 40, which can improve the mounting stability of the assembly 40 to the display screen 20.

Referring to FIG. 2, in an embodiment, the first connector 60 is a first bolt. The display module 200 and the box body 10 each define threaded holes. The first bolt passes through the threaded holes of the display module 200 and the box body 10 to mount the display module 200 and the box body 10.

In another embodiment, the first connector 60 can also be a magnet. Further, the first connector 60 can be positioned on the display module 200. The box body 10 is provided with a magnetic attraction piece that can be mounted with the magnet, or the box body 10 is made of a magnetic material. For example, steel, iron, etc. so as to realize the adsorption and connection of the box body 10 and the display module 200. The magnet may be a plate magnet, block magnet, bar magnet, circular magnet, etc., not limited herein.

When it is necessary to switch between horizontal and vertical screen modes, a vacuum adsorption device or a magnetic adsorption device is used to remove the display module 200. The display module 200 is rotated by 90°, and then set at the display window 16 for magnetic fixation.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure, up to and including the full extent established by the broad general meaning of the terms used in the claims.

What is claimed is:

1. An assembly configured to support a display screen which is adjustable according to
viewing modes, the assembly comprising:
two side support brackets positioned on both sides of the display screen, respectively, along a first direction to limit a movement of the display screen;
a top support bracket;
a bottom support bracket, the top and the bottom support bracket arranged at both ends of the display screen, respectively, along a second direction to clamp the display screen; and
a protection frame positioned on the sides of the top support bracket and the bottom support bracket along the second direction to protect the side of the display screen, and the side of the top support bracket is away from the side of the bottom support bracket; and
wherein the first direction is perpendicular to the second direction.

2. The assembly of claim 1, wherein:
the side support bracket comprises a first support plate and a first baffle, the first support plate and the first baffle are arranged in an L shape and the first support plate is connected with the first baffle.

3. The assembly of claim 2, wherein:
the assembly further comprises a buffer member, the buffer member is mounted the first support plate.

4. The assembly of claim 1, wherein:
the top support bracket comprises a second support plate and a second baffle, the second support plate and a second baffle are arranged in an L shape and the second support plate is connected with the second baffle, the top support bracket and the bottom support bracket have a same structure.

5. The assembly of claim 4, wherein
the assembly further comprises a buffer member, the buffer member is mounted the second baffle.

6. A display module mountable on a box body, the display module comprising:
a display screen, the displaying screen being adjustable according to view modes; and
an assembly configured to support the display screen which is adjustable according to viewing modes;
wherein the display screen is connected to the assembly, the assembly is connected the box body by a first connector to limit a relative positions of the assembly and the box body in a first direction and a second direction; and
wherein the first direction is perpendicular to the second direction.

7. The display module of claim 6, wherein:
the display module further comprises a glass panel, the glass panel is connected to the assembly by the first connector.

8. The display module of claim 6, wherein:
the assembly comprising:
two side support brackets positioned on both sides of a display screen, respectively, along the first direction to a the movement of the display screen;
a top support bracket;
a bottom support bracket, the top and the bottom support bracket arranged at both ends of the display screen, respectively, along the second direction to clamp the display screen; and
a protection frame positioned on the sides of the top support bracket and the bottom support bracket along the second direction to protect the side of the display screen, and the side of the top support bracket is away from the side of the bottom support bracket.

9. The display module of claim 8, wherein:
the side support bracket comprises a first support plate and a first baffle, the first support plate and the first baffle are arranged in an L shape and the first support plate is connected with the first baffle.

10. The display module of claim 9, wherein:
the assembly further comprises a buffer member, the buffer member is mounted the first support plate.

11. A multimedia device comprising:
a box body defining a displaying window, the display window being positioned corresponding to a display module;
the display module; and
four first connectors arranged in a square, and a center axis of the square is coincided with a central axis of the display module;
wherein the display module is detachably installed on the box body by the four first connectors, position of the display module correspond to the display window.

12. The multimedia device of claim 11, wherein:
the first connector is a first bolt, the box body and the display module respectively define a threaded hole, the first bolt extends through the threaded holes of the display module and the box body to mount the display module and the box body.

13. The multimedia device of claim 11, wherein:
the display module comprises a display screen and an assembly configured to support adjusts the display screen according to viewing modes;
wherein the display screen is connected to the support assembly, the assembly is connected a box body by a first connector to limit a relative positions of the assembly and the box body in a first direction and a second direction, the first direction is perpendicular to the second direction.

14. The multimedia device of claim 13, wherein:
the display module further comprises a glass panel, the glass panel is connected to the assembly by the first connector.

15. The multimedia device of claim 13, wherein:
the assembly comprises a support panel and two side support plate, the two side support plates are positioned on both sides of the support panel along the first direction, and two side support plate are connected to the support panel, the display module comprise a second connector, the display screen is connected to the two side support plates by the second connector.

16. The multimedia device of claim 13, wherein:
the assembly comprises two side support brackets, the side support brackets comprises a first support plate and a first baffle, the first support plate and the first baffle are arranged in an L shape and the first support plate is connected with the first baffle, the first support plate contacts a side of the display screen away from a display surface for support the display screen, the first baffle contacts a side of the display screen perpendicular to the first direction, two first baffles cooperate to clamp the display screen along the first direction.

17. The multimedia device of claim 16, wherein:
the assembly comprises a top support bracket and a bottom support bracket, the top and the bottom support bracket arranged at both ends of the display screen along the second direction to clamp the display screen.

18. The multimedia device of claim 11, wherein:
the box body comprises a fixing plate, the fixing plate is detachably connected to the display module.

19. The multimedia device of claim 18, wherein:
a dihedral angle formed between a plane where the fixing plate is located and a plane perpendicular to a third direction is α, 45°≤α≤90°, the third direction is the an extension direction of the box body.

20. The multimedia device of claim 11, wherein:
the box body comprises a side plate, the side plate comprises a first side plate and a second side plate, the first side plate and the second side plate are detachably connected.
